(19) United States
(12) Patent Application Publication
(10) Pub. No.: US 2026/0301609 A1
(43) Pub. Date: Oct. 1, 2026

(54) ELECTRONIC PRICE TAG SYSTEM, ELECTRONIC PRICE TAG, AND GUIDE RAIL APPARATUS FOR MOUNTING ELECTRONIC PRICE TAG

(71) Applicant: HEMA (CHINA) CO., LTD., Pudong New Area, Shanghai (CN)

(72) Inventors: Enliang SONG, Shanghai (CN); Zhenyu ZHAO, Shanghai (CN)

(21) Appl. No.: 18/996,533

(22) PCT Filed: Nov. 22, 2023
(86) PCT No.: PCT/CN2023/133363

§ 371 Date: Jan. 17, 2025

(30) Foreign Application Priority Data
Nov. 23, 2022 (CN) 202211475829.8

(51) Int. Cl. G09F 3/20; H05K 5/02

(52) U.S. Cl. CPC G09F 3/208; H05K 5/0247

(57) ABSTRACT

An electronic price tag system, an electronic price tag (2), and a guide rail apparatus (1). The guide rail apparatus (1) comprises a guide rail (10); several positioning electrodes (11); and first resistors (12). The electronic price tag (2) comprises a price tag body (20), and a power-source positive-electrode connecting piece (21), a power-source negative-electrode connecting piece (22) and conductive contact pieces (23). The electronic price tag (2) is configured to make the conductive contact pieces (23) come into contact with one positioning electrode (11), such that the power-source positive-electrode connecting piece (21) outputs a high level and measures the voltage across the two ends of the second resistor (25), and the voltage across the two ends of the second resistor (25) is configured to be used for determining whether the price tag body (20) is located at a designated target position on the guide rail (10).

The present application claims priority to Chinese Patent Application No. 202211475829.8, filed with the China Patent Office on Nov. 23, 2022 and titled “ELECTRONIC PRICE TAG SYSTEM, ELECTRONIC PRICE TAG, AND GUIDE RAIL APPARATUS FOR MOUNTING ELECTRONIC PRICE TAG”, which is incorporated herein by reference in its entirety.

### TECHNICAL FIELD

The present disclosure relates to the technical field of new retail, and in particular, to an electronic price tag system, an electronic price tag, and a guide rail apparatus for mounting the electronic price tag.

### BACKGROUND

As the infrastructure for the digitization in the supermarket and retail industry, the electronic price tag system has been replicated in large quantities within the industry. It is desired that through simple and low-cost hardware and software upgrades, the electronic price tag system's own basic capabilities related to fine positioning will be enhanced, achieving more digital value mining of the electronic price tag system hardware in retail scenarios.

With reference to FIG. 1, a guide rail for mounting an electronic price tag is arranged on a board at each layer of a shelf, so as to display price, origin and other attributes of a corresponding commodity object on the electronic price tag, and there is a unique corresponding relationship between the electronic price tag and the corresponding commodity. For example, an electronic price tag corresponding to a commodity object 1 is 131.

In usual situations, in large supermarkets or chain supermarkets, according to market demands, a designated target commodity is required to be placed at a designated target placement position on a designated target shelf, so as to improve the exposure rate and sales of the target commodity. However, in practice, there is a situation where the target commodity is not placed at the target placement position as required, which needs a lot of manual efforts for verification, thereby increasing the management costs of large supermarkets and chain supermarkets.

### SUMMARY

The present disclosure provides an electronic price tag system, an electronic price tag, and a guide rail apparatus for mounting the electronic price tag, so as to solve one or more of the above technical problems.

In a first aspect, the present disclosure provides an electronic price tag system including: a guide rail apparatus including a guide rail, a plurality of positioning electrodes successively arranged on the guide rail at intervals along an extension direction of the guide rail, and first resistors connected in series between adjacent two of the positioning electrodes, wherein positioning electrode located at the tail end is grounded; an electronic price tag including a price tag body, and a power-source positive-electrode connecting piece, a power-source negative-electrode connecting piece and a conductive contact piece, which are arranged on the price tag body, wherein the power-source positive-electrode connecting piece and the power-source negative-electrode connecting piece are configured to be used for connecting to a power source, and the power-source positive-electrode connecting piece and the conductive contact piece are electrically connected by means of a second resistor; wherein the electronic price tag is configured to make the conductive contact piece come into contact with one of the positioning electrodes in a positioning measurement mode after the electronic price tag is mounted on the guide rail, such that the power-source positive-electrode connecting piece outputs a high level and a voltage across the second resistor is measured, and the voltage across the second resistor is configured to be used for determining whether the price tag body is at a target position on the guide rail.

In a second aspect, the present disclosure further provides an electronic price tag. The electronic price tag of the present disclosure includes a price tag body, and a power-source positive-electrode connecting piece, a power-source negative-electrode connecting piece and a conductive contact piece, which are arranged on the price tag body, wherein the power-source positive-electrode connecting piece and the power-source negative-electrode connecting piece are configured to be used for connecting to a power source, and the power-source positive-electrode connecting piece and the conductive contact piece are electrically connected by means of a second resistor; the electronic price tag is configured to make the conductive contact piece come into contact with a positioning electrode on a guide rail in a positioning measurement mode after the electronic price tag is mounted on the guide rail, such that the power-source positive-electrode connecting piece outputs a high level and a voltage across the second resistor is measured, wherein the voltage across the second resistor is configured to be used for determining whether the price tag body is at a target position on the guide rail.

In a third aspect, the present disclosure further provides a guide rail apparatus for mounting the electronic price tag as described in any one of the above, the guide rail apparatus including a guide rail, a plurality of positioning electrodes successively arranged on the guide rail at intervals along an extension direction of the guide rail, and first resistors connected in series between adjacent two of the positioning electrodes, wherein the positioning electrode located at the tail end is grounded.

It need be noted that both the electronic price tag of the present disclosure and the guide rail apparatus for mounting the electronic price tag have the same or corresponding technical features as the electronic price tag system described above, and therefore also have the same technical effects, which will not be repeated herein.

Additionally, the above summary is for illustrative purposes only and is not intended to be limiting in any way. In addition to the schematic aspects, implementations, and features described above, aspects, implementations, and features of the present application will be readily apparent by referring to the drawings and the following detailed description.

### BRIEF DESCRIPTION OF THE DRAWINGS

The drawings, which are incorporated in and constitute a part of the specification, show embodiments of the present disclosure and serve, along with the description thereof, to explain the principles of the present disclosure.

FIG. 1 shows a schematic diagram of a corresponding relationship between electronic price tags and placed commodities on a shelf.

FIG. 2 shows a schematic structural diagram of a guide rail apparatus of the present disclosure in an embodiment.

FIG. 3 shows a schematic structural diagram of an electronic price tag of the present disclosure in an embodiment.

FIG. 4 shows a diagram of the working principle of a chip of an electronic price tag in an embodiment.

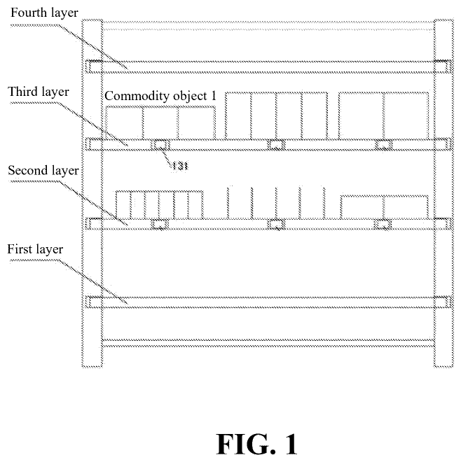

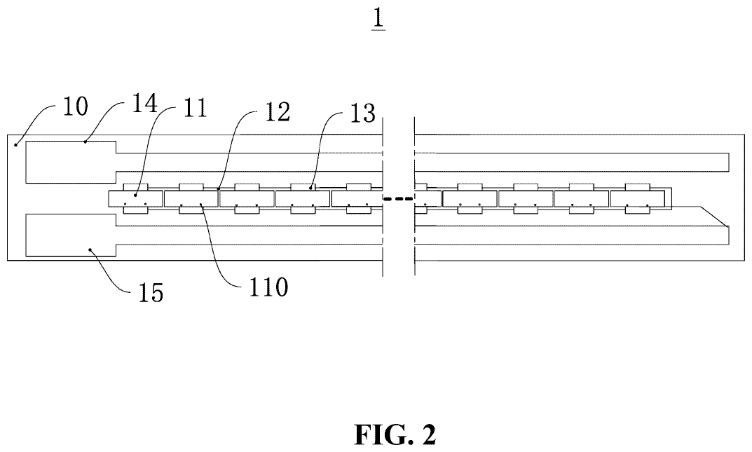

A one-to-one corresponding relationship between the respective component names and reference numerals in FIGS. 2 to 4 is as follows.

1 guide rail apparatus: 10 guide rail, 11 positioning electrode, 12 first resistor, 13 resistor pad, 14 power-source positive-electrode contact wire, 15 power-source negative-electrode contact wire.

2 electronic price tag: 20 price tag body, 21 power-source positive-electrode connecting piece, 22 power-source negative-electrode connecting piece, 23 conductive contact piece, 24 chip, 241 first port, 242 second port, 243 third port, and 25 second resistor.

### DETAILED DESCRIPTION

Various exemplary embodiments of the present disclosure will now be described in detail with reference to the drawings. It should be noted that the relative arrangement of components and steps, numerical expressions, and numerical values set forth in these embodiments do not limit the scope of the present disclosure unless specifically stated otherwise.

The following description of at least one exemplary embodiment is merely illustrative in nature and, in no way, serves as any limitation on the present disclosure and application or use thereof.

Techniques, methods, and devices known to those of ordinary skill in the relevant field may not be discussed in detail, but where appropriate, the techniques, methods, and devices should be considered as part of the specification.

In all of the instances shown and discussed here, any specific value should be construed as an example only, not as a limitation. Accordingly, other instances of the exemplary embodiment may involve different values.

It should be noted that like reference numerals and letters denote similar items in the following drawings, and thus, once a certain item is defined in a drawing, it need not be further discussed in the subsequent drawings.

The present disclosure provides an electronic price tag system. The electronic price tag system of the present disclosure includes a guide rail apparatus and an electronic price tag, wherein the guide rail apparatus includes a guide rail, a plurality of positioning electrodes successively arranged on the guide rail at intervals end to end along an extension direction of the guide rail, and first resistors connecting adjacent two of the positioning electrodes in series, wherein a positioning electrode at the tail is grounded. The electronic price tag includes a price tag body, and a power-source positive-electrode connecting piece, a power-source negative-electrode connecting piece and a conductive contact piece, which are arranged on the price tag body, wherein the power-source positive-electrode connecting piece and the power-source negative-electrode connecting piece are configured to be used for connecting to a power source, and the power-source positive-electrode connecting piece and the conductive contact piece are electrically connected by means of a second resistor. Moreover, the electronic price tag is configured to make the conductive contact piece come into contact with one of the positioning electrodes in a positioning measurement mode after the electronic price tag is mounted on the guide rail, such that the power-source positive-electrode connecting piece outputs a high level and a voltage across the second resistor is measured, and the voltage across the second resistor is configured to be used for determining whether the price tag body is at a designated target position on the guide rail.

Here is the positioning principle of this electronic price tag system. A sum of a length of each of the positioning electrodes along the extension direction of the guide rail and a gap between the positioning electrode and an adjacent positioning electrode is taken as the minimum measurement unit. After the conductive contact piece on the electronic price tag comes into contact with any one of the positioning electrodes, the electronic price tag forms a current loop with the positioning electrode with which it is currently in contact to the positioning electrode at the tail. When the power supply outputs the high level by the power-source positive-electrode connecting piece, the voltage across the second resistor may be detected, and an actual position of the electronic price tag on the guide rail then may be obtained in view of the principle of voltage division. The actual position is then compared with the target position. According to a comparison result, it can be known whether the electronic price tag is placed in place. If it is not placed at the target position, an alarm may be sent to remind the user without manual verification, thereby greatly reducing the management cost.

In the electronic price tag system of the present disclosure, there is no positioning detection circuit arranged on the guide rail. Instead, the sum of the length of each of the positioning electrodes and the gap between two adjacent positioning electrodes is ingeniously taken as the minimum measurement unit, a positioning detection circuit constituted by means of the cooperation of the positioning electrode and the electronic price tag is utilized to acquire the voltage of the second resistor, and with the detected voltage, the actual position of the electronic price tag on the guide rail may be determined, which is simple in structure and easy to achieve.

For better understanding, a specific structure and the working principle of the electronic price tag system of the present disclosure will be described in detail with reference to FIGS. 2 to 4. It need be explained that the present disclosure further provides an electronic price tag and a guide rail apparatus for mounting the electronic price tag. In order to keep the text concise, the introduction of the electronic price tag and the guide rail apparatus for mounting the electronic price tag will be made herein along with the description of the electronic price tag system, and the two will not be illustrated separately.

With reference to FIG. 2, the electronic price tag system of the present disclosure includes a guide rail apparatus 1 for mounting the electronic price tag. This guide rail apparatus 1 includes a guide rail 10, which is usually a strip-shaped metal piece, plastic piece or resin piece. The guide rail 10 is configured to extend along a length direction of a board of a shelf and to be substantially consistent with a length of a space for placing commodities on the board. The guide rail 10 is connected in a fixed or detachable manner onto a cross beam of the board of the shelf. A front part of the guide rail 10 is provided with a mounting slot, and the electronic price tag is mounted within the mounting slot in a detachable manner. It need be explained that the front part refers to a side of the shelf facing towards a user, so as to make it convenient for the user to take and put the electronic price tag from and on the shelf.

The guide rail apparatus 1 may further include a positioning circuit board including a circuit board body, a plurality of positioning electrodes 11 successively arranged on the circuit board body at intervals end to end along an extension direction of the guide rail 10, and first resistors 12 connected in series between adjacent two of the positioning electrodes 11. Of course, the positioning electrodes 11 and the first resistors 12 may be directly arranged on the guide rail 10, so as to omit the positioning circuit board.

For example, the guide rail 10 has a length of 850 mm, and excluding the 20 mm lengths of transition regions between left and right ends of the guide rail 10 and the nearest positioning electrodes 11, the remaining length of the guide rail 10 is 810 mm, that is to say, there may be 81 positioning electrodes 11 arranged on the guide rail 10. For the convenience of recording, the 81 positioning electrodes 11 are successively numbered as S1-S81 end to end. Of course, in other embodiments, the positioning electrodes 11 at the head and tail ends are aligned with the left and right ends of the guide rail 10.

In order to ensure the accuracy of the measurement precision, the gap between two adjacent positioning electrodes 11 should be controlled within a range as small as possible. For example, the gap between two adjacent positioning electrodes 11 is 0.1 mm, and it is not convenient to arrange the first resistors 12 within such a small gap.

To this end, with reference to FIG. 2, in this embodiment, the positioning electrodes 11 are disposed on an end face of the guide rail 10, and the second resistors are disposed on an end face of the guide rail 10 opposite to the positioning electrodes 11.

In this way, the guide rail apparatus may make full use of both side faces of the guide rail to arrange the positioning electrodes 11 and the first resistors 12.

In addition, the first resistors are a carbon film resistor that is printed onto the guide rail 10 or the positioning circuit board. Such method may be implemented on a plane and avoid components from protruding. After being covered with carbon oil, the first resistors have the characteristics of dirt corrosion resistance, high engineering reliability, and lower implementation cost. Additionally, the carbon film resistor is convenient for mass printing, which ensures that more positioning electrodes 11 are segmented, otherwise the implementation cost is high.

In an implementation, the guide rail apparatus 1 further includes resistor pads 13 located on a same end face as the first resistors 12, the positioning electrodes 11 and the resistor pads 13 are connected by via holes 110 provided on the guide rail 10, and two adjacent first resistors 12 are connected by the resistor pads 13. Also, the resistor pads 13 are a carbon film resistor pad.

It need be explained that the carbon film resistor pad has the same effect as the carbon film resistor, which has been fully explained previously and will not be repeated here.

Additionally, in case that the carbon film resistor pad has the carbon film resistor, along the extension direction of the guide rail 10, a sum of a length of a positioning electrode 11 and a gap between two adjacent positioning electrodes 11 forms the minimum measurement unit. For example, the positioning electrode 11 has a length of 9.9 mm, and the gap between two adjacent positioning electrodes 11 is 0.1 mm, that is to say, the minimum measurement unit formed by the sum of the positioning electrode 11 and the gap between two adjacent positioning electrodes 11 is 10 mm. The number of positioning electrodes 11 depends on the length of the guide rail 10. It need be explained that, in some other embodiments, the minimum measurement unit formed by the sum of the positioning electrode 11 and the gap between two adjacent positioning electrodes 11 is between 9 mm and 11 mm.

Based on this, when the electronic price tag is placed at a certain position on the guide rail 10, if an actual position of the electronic price tag can be obtained automatically, and a relationship between the actual position and a designated target position on a target shelf is then compared, it may be judged, according to the comparison result, whether the electronic price tag is placed at the designated target position, for example, a target position on the target shelf close to a gate where a target commodity such as a new seasonal product or a saleable product is placed. If the comparison result is that the actual position of the electronic price tag is not consistent with the designated target position, the user may be notified of an update. To this end, the electronic price tag and the guide rail apparatus need to cooperate to acquire the actual position of the electronic price tag on the guide rail 10.

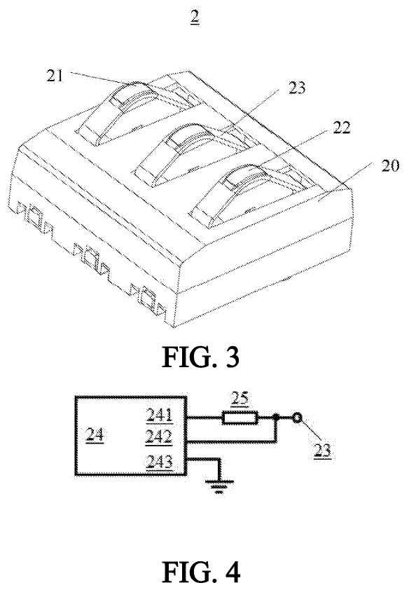

In an implementation, with reference to FIG. 3, in this embodiment, the electronic price tag 2 includes a price tag body 20, and a power-source positive-electrode connecting piece 21, a power-source negative-electrode connecting piece 22 and a conductive contact piece 23, which are arranged on the price tag body 20, wherein the power-source positive-electrode connecting piece 21 and the power-source negative-electrode connecting piece 22 are configured to communicate with a power source, and the power-source positive-electrode connecting piece 21 and the conductive contact piece 23 are connected in series by means of a second resistor.

The price tag body 20 is usually a cuboid element made of an insulating material, and is further used for mounting a display screen that, in a case where the power source supplies power, may display relevant information of a commodity corresponding to the electronic price tag 2, such as name, price, and origin. No limitation is made herein on specific display contents.

The electronic price tag 2 is configured to make the conductive contact piece 23 come into contact with one of the positioning electrodes 11 in a positioning measurement mode after the electronic price tag 2 is mounted on the guide rail 10, so as to connect the power source with the power-source positive-electrode connecting piece 21 and the power-source negative-electrode connecting piece 22 and a voltage across the second resistor is detected.

At this time, the power source, the second resistor, the positioning electrode 11 currently in contact with a first conductive contact piece, and the first resistor 12 between two adjacent positioning electrodes 11 among these positioning electrodes 11 constitute a complete current loop, and then the voltage across the second resistor is measured.

It need be explained that the electronic price tag 2 of the present disclosure may be equipped internally with a dry battery or rechargeable battery, or may be externally connected with a power source that is connected with the power-source positive-electrode connecting piece 21 and the power-source negative-electrode connecting piece 22. In the embodiment, the power source is provided by the guide rail apparatus 1 for the electronic price tag 2.

In an implementation, with continued reference to FIG. 2, the guide rail apparatus 1 further includes a power-source positive-electrode contact wire 14 and a power-source negative-electrode contact wire 15, which are parallel to each other and are provided separately on two sides of the positioning electrodes 11. The positioning electrode 11 at the tail end is connected with the power-source negative-electrode contact wire 14, and the two are connected with the ground wire.

After the electronic price tag 2 is mounted on the guide rail apparatus 1, the power-source positive-electrode connecting piece 21 of the electronic price tag 2 comes into contact with the power-source positive-electrode contact wire 14, the power-source negative-electrode connecting piece 22 of the electronic price tag 2 comes into contact with the power-source negative-electrode contact wire 15, and the conductive contact piece 23 of the electronic price tag 2 comes into contact with one of the positioning electrodes 11.

In the same manner, the power source of the guide rail apparatus 2 may be an internal dry battery or rechargeable battery, or may be an external power source.

With continued reference to FIG. 3, the power-source positive-electrode connecting piece 21, the power-source negative-electrode connecting piece 22 and the conductive contact piece 23 are arc-shaped elastic pieces bent towards the guide rail 10 side.

The arc-shaped elastic pieces may reduce a lateral resistance when the electronic price tag 2 moves over the guide rail, and alleviate the wear of the positioning electrodes 11. At the same time, the design of the arc-shaped elastic pieces may also ensure the gap between two adjacent positioning electrodes, and may not lead to lost connection of the arc-shaped elastic pieces with the positioning electrodes. At a gap position of 0.1 mm, the arc-shaped elastic pieces may be connected with front and rear positioning electrodes, thereby ensuring the accuracy of the voltage detection value.

With reference to FIG. 4, the electronic price tag 2 further includes a chip 24 arranged on the price tag body 20 and including a first port 241, a second port 242, and a third port 243. The first port 241 is connected with the conductive contact piece 23 by means of the second resistor 25, the second port 242 is connected between the second resistor 25 and the conductive contact piece 23, and the third port is grounded. The first port 241 is connected with the power-source positive-electrode connecting piece 21, the second port 242 is used for measuring the voltage across the second resistor 25, and the third port 243 is connected with the power-source negative-electrode connecting piece 22 and the ground wire.

In an implementation, the first port 241 is a general-purpose input/output port, and the second port 242 is a digital-to-analog conversion port. When the electronic price tag system is in the positioning measurement mode, a high level is input to the first port 241. When the electronic price tag system is in a normal working mode, that is to say, the electronic price tag system is in a non-positioning measurement mode, the first port 241 is set to receive an analog input, and the second port 242 is set to receive an analog input, so as to ensure that the positioning electrodes 11 are in a non-electrically connected state.

The digital-to-analog conversion port performs short-time measurement, and the positioning measurement may be done in a millisecond level, which ensures that the positioning electrodes 11 are not electrically connected most of the time.

Of course, in some other embodiments, a voltage measuring element may be connected in parallel across the second resistor 25, so as to measure the voltage across the second resistor 25.

After the electronic price tag system detects the voltage of the second resistor 25, the electronic price tag 2 is communicatively connected with a server in a wired or wireless manner. For example, when the electronic price tag transmits data back to the server, the communication link may be a wireless channel such as Bluetooth and Wi-Fi, or may be a wired channel such as CAN, RS485 and Ethernet.

The server acquires the voltage of the second resistor 25, and then determines the actual position of the electronic price tag 2 on the guide rail 10. A specific way of determination is achieved by the following Formula (I):

$$L = A + \{ [ ( {R}_{2} \times U ) \div {U}_{2} - {R}_{2} ] \div {R}_{1} \} \times l \qquad Formula ( I ) .$$

where L represents the distance from the leftmost end of the guide rail to the electronic price tag, R₂ represents the second resistor, U represents the high level input by the power-source positive-electrode connecting piece, U₂ represents the voltage across the second resistor, R₁ represents the first resistor, and 1 represents the sum of the length of one positioning electrode in the extension direction of the guide rail and the gap between two adjacent positioning electrodes.

It need be explained that the voltage across the second resistor 25 is measured 10 times at random times, and the minimum value is taken.

Obviously, in the electronic price tag system, there is no positioning detection circuit arranged on the guide rail 10. Instead, the sum of the length of each of the positioning electrodes 11 and the gap between two adjacent positioning electrodes is ingeniously taken as the minimum measurement unit, a positioning detection circuit constituted by means of the cooperation of the positioning electrode 11 and the electronic price tag 2 is utilized to acquire the voltage of the second resistor, and with the detected voltage, the actual position of the electronic price tag on the guide rail may be determined, which is simple in structure and easy to achieve.

After the electronic price tag measures the voltage across the second resistor, the electronic price tag and the server are communicatively connected in a wired and wireless manner, and the voltage across the second resistor 25 is transmitted to the server, which internally has a storage unit and a calculation unit. The storage unit stores the actual length of the guide rail 10, as well as the various parameters in the Formula (I), and the calculation unit calculates the actual position of the electronic price tag on the guide rail 10 according to the Formula (I), that is, the actual distance from the left end of the guide rail to the contact point between the electronic price tag 2 and a positioning electrode piece 11.

An instruction sent by the server is to place the electronic price tag at the target position of the guide rail on the shelf, and the numerical value of the target position may be a target distance calculated from the left end of the guide rail as a starting end. Of course, this numerical value is not a single numerical value, but may be a numerical range. This range covers an acceptable amount of misplacement deviation, which may be set by those skilled in the art based on actual situations, and is not limited herein.

After the calculation unit obtains the actual distance from the left end of the guide rail to the contact point between the electronic price tag and the positioning electrode piece, the server judges whether the actual distance is consistent with the target distance. If the actual distance is consistent with the target distance, then it means that the electronic price tag is placed at the designated target position; and if the actual distance is not consistent with the target distance, then it means that the electronic price tag is misplaced, and the server may send an alarm signal to remind the user to place the electronic price tag again.

For better understanding, the working principle of the electronic price tag system of the present disclosure will be illustrated in detail below with reference to FIG. 2 to FIG. 4 in conjunction with an application scenario.

A chain supermarket receives a server instruction that requires a new seasonal commodity A to be placed at a target position B on a third layer of a target shelf at an entrance of the supermarket. Then the supermarket staff places the electronic price tag 2 on the guide rail 10 on the third layer of the target shelf. At this time, the conductive contact piece 23 on the electronic price tag 2 comes into contact with one of the positioning electrodes 11 on the guide rail 10, the power-source positive-electrode connecting piece 21 comes into contact with the power-source positive-electrode contact wire 14 on the guide rail 10, the power-source negative-electrode connecting piece 22 comes into contact with the power-source negative-electrode contact wire 15 on the guide rail 10, and the power source electrically conducts the power-source positive-electrode contact wire 14 and the power-source negative-electrode contact wire 15.

When the electronic price tag system needs to measure the actual position of the electronic price tag 2 on the shelf, a high level is input to the general-purpose input/output port of the chip 24, and the digital-to-analog conversion port thereof measures the voltage at the two ends of the second resistor 25.

The server acquires the voltage at the two ends of the second resistor 25, calculates, based on the voltage and according to the Formula (I), the actual distance from the left end of the guide rail 10 to the positioning electrode 11 in contact with the electronic price tag 2, and judges whether the actual distance is consistent with the target distance given by the server. If the actual distance is consistent with the target distance, then it means that the electronic price tag 2 is placed at the designated target position; and if the actual distance is not consistent with the target distance, then it means that the electronic price tag 2 is misplaced, and the server may send an alarm signal to remind the user to place the electronic price tag again.

Various embodiments of the present disclosure have been described above, and the illustration made above is exemplary, not exhaustive, and is not limited to the disclosed embodiments. Without departing from the scope and spirit of the illustrated embodiments, many modifications and variations will be apparent to those of ordinary skill in this technical field. The terms used herein are chosen to be intended to best explain the principles of the embodiments, practical applications, or improvements to the technologies in the marketplace, or to enable others of ordinary skill in this technical field to understand the embodiments disclosed herein. The scope of the present disclosure is defined by the appended claims.

1. An electronic price tag system, comprising:
a guide rail apparatus (1) comprising a guide rail (10), a plurality of positioning electrodes (11) successively arranged on the guide rail (10) at intervals along an extension direction of the guide rail (10), and first resistors (12) connected in series between adjacent two of the positioning electrodes (11), wherein a positioning electrode (11) located at a tail end is grounded;
an electronic price tag (2) comprising a price tag body (20), and a power-source positive-electrode connecting piece (21), a power-source negative-electrode connecting piece (22) and a conductive contact piece (23), which are arranged on the price tag body (20), wherein the power-source positive-electrode connecting piece (21) and the power-source negative-electrode connecting piece (22) are configured to be used for connecting to a power source, and the power-source positive-electrode connecting piece (21) and the conductive contact piece (23) are electrically connected by means of a second resistor (25);
wherein the electronic price tag (2) is configured to make the conductive contact piece (23) come into contact with one of the positioning electrodes (11) in a positioning measurement mode after the electronic price tag (2) is mounted on the guide rail (10), such that the power-source positive-electrode connecting piece (21) outputs a high level and a voltage across the second resistor (25) is measured, and the voltage across the second resistor (25) is configured to be used for determining whether the price tag body (20) is at a target position on the guide rail (10).

2. The electronic price tag system according to claim 1, wherein the electronic price tag (2) is further configured to cut off an input electrical signal of the power-source positive-electrode connecting piece (21) in a normal working mode after the electronic price tag (2) is mounted on the guide rail (10).

3. The electronic price tag system according to claim 1, wherein the guide rail apparatus (1) further comprises a power-source positive-electrode contact wire (14) and a power-source negative-electrode contact wire (15), which are connected to the power source, and the positioning electrode (11) at the tail end is connected with the power-source negative-electrode contact wire (15); and
the electronic price tag (2) is configured in such a manner that after the electronic price tag (2) is mounted on the guide rail (10), the power-source positive-electrode connecting piece (21) comes into contact with the power-source positive-electrode contact wire (14), and the power-source negative-electrode connecting piece (22) comes into contact with the power-source negative-electrode contact wire (15).

4. The electronic price tag system according to claim 1, wherein the conductive contact piece (23) is an arc-shaped contact piece protruding towards the positioning electrode (11).

5. The electronic price tag system according to claim 1, wherein a gap between adjacent positioning electrodes (11) is 0.1 mm.

6. The electronic price tag system according to claim 1, wherein the positioning electrodes (11) are arranged on an end face of the guide rail (10), and the first resistors (12) are arranged on an end face of the guide rail (10) opposite to the positioning electrodes (11).

7. The electronic price tag system according to claim 6, wherein the guide rail apparatus (1) further comprises resistor pads (13) located on a same face as the first resistors (12), the positioning electrodes (11) and the resistor pads (13) are connected by via holes provided on the guide rail (10), and adjacent two of the first resistors (12) are connected by means of the resistor pads (13).

8. The electronic price tag system according to claim 7, wherein the resistor pads (13) are a carbon film resistor pad and/or the first resistors (12) are a carbon film resistor.

9. The electronic price tag system according to claim 1, wherein the electronic price tag (2) comprises:
a chip (24) arranged on the price tag body (20), wherein a first port (241) of the chip (24) is connected to the power-source positive-electrode connecting piece (21) and the second resistor (25), a second port (242) of the chip (24) is used for measuring the voltage across the second resistor (25), and a third port (243) of the chip (24) is grounded.

10. The electronic price tag system according to claim 9, wherein the first port (241) is a general-purpose input/output port and/or the second port (242) is a digital-to-analog conversion port.

11. An electronic price tag, the electronic price tag (2) comprising a price tag body (20), and a power-source positive-electrode connecting piece (21), a power-source negative-electrode connecting piece (22) and a conductive contact piece (23), which are arranged on the price tag body (20), wherein the power-source positive-electrode connecting piece (21) and the power-source negative-electrode connecting piece (22) are configured to be used for connecting to a power source, and the power-source positive-electrode connecting piece (21) and the conductive contact piece (23) are electrically connected by means of a second resistor (25);
the electronic price tag (2) is configured to make the conductive contact piece (23) come into contact with a positioning electrode (11) on a guide rail (10) in a positioning measurement mode after the electronic price tag (2) is mounted on the guide rail (10), such that the power-source positive-electrode connecting piece (21) outputs a high level and a voltage across the second resistor (25) is measured, wherein the voltage across the second resistor (25) is configured to be used for determining whether the price tag body (20) is at a target position on the guide rail (10).

12. A guide rail apparatus for mounting the electronic price tag of claim 11, the guide rail apparatus (1) comprising a guide rail (10) and a plurality of positioning electrodes (11) successively arranged on the guide rail (10) at intervals along an extension direction of the guide rail (10), and first resistors (12) connected in series between adjacent two of the positioning electrodes (11), wherein a positioning electrode (11) located at a tail end is grounded.

13. The guide rail apparatus according to claim 12, wherein a gap between adjacent positioning electrodes (11) is 0.1 mm.

14. The guide rail apparatus according to claim 12, wherein the first resistors (12) are a carbon film resistor.

15. The electronic price tag system according to claim 2, wherein the positioning electrodes (11) are arranged on an end face of the guide rail (10), and the first resistors (12) are arranged on an end face of the guide rail (10) opposite to the positioning electrodes (11).

16. The electronic price tag system according to claim 3, wherein the positioning electrodes (11) are arranged on an end face of the guide rail (10), and the first resistors (12) are arranged on an end face of the guide rail (10) opposite to the positioning electrodes (11).

17. The electronic price tag system according to claim 4, wherein the positioning electrodes (11) are arranged on an end face of the guide rail (10), and the first resistors (12) are arranged on an end face of the guide rail (10) opposite to the positioning electrodes (11).

18. The electronic price tag system according to claim 5, wherein the positioning electrodes (11) are arranged on an end face of the guide rail (10), and the first resistors (12) are arranged on an end face of the guide rail (10) opposite to the positioning electrodes (11).

19. The electronic price tag system according to claim 2, wherein the electronic price tag (2) comprises:
a chip (24) arranged on the price tag body (20), wherein a first port (241) of the chip (24) is connected to the power-source positive-electrode connecting piece (21) and the second resistor (25), a second port (242) of the chip (24) is used for measuring the voltage across the second resistor (25), and a third port (243) of the chip (24) is grounded.

20. The electronic price tag system according to claim 3, wherein the electronic price tag (2) comprises:
a chip (24) arranged on the price tag body (20), wherein a first port (241) of the chip (24) is connected to the power-source positive-electrode connecting piece (21) and the second resistor (25), a second port (242) of the chip (24) is used for measuring the voltage across the second resistor (25), and a third port (243) of the chip (24) is grounded.
